(19) United States
(12) Patent Application Publication
(10) Pub. No.: US 2026/0004823 A1
(43) Pub. Date: Jan. 1, 2026

(54) MEMORY DEVICE AND OPERATING METHOD OF THE SAME

(71) Applicant: SK hynix Inc., Gyeonggi-do (KR)

(72) Inventor: Yeonsu JANG, Gyeonggi-do (KR)

(21) Appl. No.: 18/957,898

(22) Filed: Nov. 25, 2024

(30) Foreign Application Priority Data
Jun. 28, 2024 (KR) 10-2024-0085554

(51) Int. Cl. G11C 7/06

(52) U.S. Cl. CPC G11C 7/06

(57) ABSTRACT

A memory device includes a first driving circuit configured to supply a second voltage to a supply terminal of a first voltage when the first voltage is lower than a first threshold voltage, in response to a first enable signal; a second driving circuit configured to supply the second voltage to the supply terminal of the first voltage when the first voltage is lower than a second threshold voltage, in response to a second enable signal, the second threshold voltage having a lower voltage level than the first threshold voltage; and a sense amplification circuit coupled to the supply terminal of the first voltage.

### CROSS-REFERENCE TO RELATED APPLICATION(S)

This application claims priority under 35 U.S.C. § 119 to Korean Patent Application No. 10-2024-0085554, filed on Jun. 28, 2024, the disclosure of which is incorporated herein by reference in its entirety.

### BACKGROUND

### 1. Field

Various embodiments of the present disclosure relate to a semiconductor design technique, and more particularly, to a memory device using an internal voltage and an operating method of the memory device.

### 2. Description of the Related Art

A memory device includes a plurality of memory cells arranged at intersections of a plurality of bit lines and a plurality of word lines, and a plurality of sensing amplification circuits for amplifying data loaded on the plurality of bit lines.

The plurality of sensing amplification circuits use an internal voltage. The internal voltage refers to a core voltage (VCORE) supplied to a core region of the memory device.

As integration of the memory device increases due to technological advancement, a voltage drop occurs in the internal voltage. When the voltage drop occurs in the internal voltage, offset characteristics of the sensing amplification circuit using the internal voltage deteriorates. As a result, the sensing margin of the sensing amplification circuit decreases.

Therefore, a technology capable of monitoring and compensating for the voltage drop in the internal voltage is needed.

### SUMMARY

Various embodiments of the present disclosure are directed to a memory device capable of monitoring an internal voltage and differentially compensating for the internal voltage according to an amount of voltage drop in the internal voltage, and an operating method of the memory device.

In accordance with an embodiment of the present disclosure, a memory device may include a first driving circuit configured to supply a second voltage to a supply terminal of a first voltage when the first voltage is lower than a first threshold voltage, in response to a first enable signal; a second driving circuit configured to supply the second voltage to the supply terminal of the first voltage when the first voltage is lower than a second threshold voltage, in response to a second enable signal, the second threshold voltage having a lower voltage level than the first threshold voltage; and a sense amplification circuit coupled to the supply terminal of the first voltage.

In accordance with an embodiment of the present disclosure, a memory device may include a sense amplification circuit configured to perform, based on an internal voltage, a first operation during a first operation period and a second operation during a second operation period; a main driving circuit configured to supply, in response to an enable signal, a predetermined voltage to a supply terminal of the internal voltage when the internal voltage is lower than a threshold voltage during the first operation period and the second operation period, the threshold voltage having a lower voltage level than the internal voltage; a first auxiliary driving circuit configured to supply, in response to a first enable signal, the predetermined voltage to the supply terminal of the internal voltage when the internal voltage is lower than a first threshold voltage during the first operation period and the second operation period, the first threshold voltage having a lower voltage level than the threshold voltage; and a second auxiliary driving circuit configured to supply, in response to a second enable signal, the predetermined voltage to the supply terminal of the internal voltage when the internal voltage is lower than a second threshold voltage during the second operation period, the second threshold voltage having a lower voltage level than the first threshold voltage.

In accordance with an embodiment of the present disclosure, an operating method of a memory device may include continuously monitoring, during a first operation period and a second operation period, a voltage drop in an internal voltage based on a first threshold voltage; supplying, during the first operation period and the second operation period, a predetermined voltage to the supply terminal of the internal voltage according to a result of the continuous monitoring when the internal voltage varies by a first voltage drop amount or more; selectively monitoring, during the first operation period and the second operation period, the voltage drop in the internal voltage based on the first threshold voltage according to the result of the continuous monitoring; and additionally supplying, during the first operation period and the second operation period, the predetermined voltage to the supply terminal of the internal voltage according to a result of the selective monitoring when the internal voltage varies by a second voltage drop amount or more.

### BRIEF DESCRIPTION OF THE DRAWINGS

FIG. 1 is a block diagram illustrating a memory device in accordance with an embodiment of the present disclosure.

FIG. 2 is a block diagram illustrating in detail a first monitoring circuit illustrated in FIG. 1, in accordance with an embodiment of the present disclosure.

FIG. 3 is a block diagram illustrating in detail a second monitoring circuit illustrated in FIG. 1, in accordance with an embodiment of the present disclosure.

FIG. 4 is a block diagram illustrating in detail a third monitoring circuit illustrated in FIG. 1, in accordance with an embodiment of the present disclosure.

FIG. 5 is a timing diagram for describing an operation of a memory device in accordance with an embodiment of the present disclosure.

FIG. 6 is a block diagram illustrating a memory device in accordance with an embodiment of the present disclosure.

### DETAILED DESCRIPTION

Various embodiments of the present disclosure are described below with reference to the accompanying drawings, in order to describe in detail the embodiments of the present disclosure so that those with ordinary skill in art to which the present disclosure pertains may easily carry out the technical spirit of the present disclosure.

It will be understood that when an element is referred to as being “connected to” or “coupled to” another element, the element may be directly connected to or coupled to the other element, or electrically connected to or coupled to the other element with one or more elements interposed therebetween. In addition, it will also be understood that the terms “comprises,” “comprising,” “includes,” and “including” when used in this specification do not preclude the presence of one or more other elements, but may further include or have the one or more other elements, unless otherwise mentioned. In the description throughout the specification, some components are described in singular forms, but the embodiments of the present disclosure are not limited thereto, and it will be understood that the components may be formed in plural.

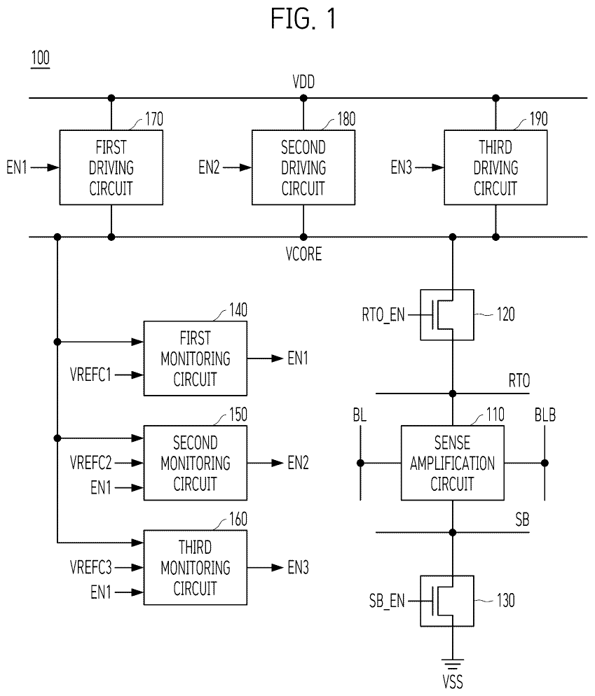

FIG. 1 is a block diagram illustrating a memory device 100 in accordance with an embodiment of the present disclosure.

Referring to FIG. 1, the memory device 100 may include a sense amplification circuit 110, a first power supply circuit 120, a second power supply circuit 130, a first monitoring circuit 140, a second monitoring circuit 150, a third monitoring circuit 160, a first driving circuit 170, a second driving circuit 180, and a third driving circuit 190.

The sense amplification circuit 110 may be coupled between a first power line RTO and a second power line SB. The sense amplification circuit 110 may perform a first operation during a first operation period and perform a second operation during a second operation period subsequent to the first operation period. For example, the first operation may include a mismatch cancellation operation, and the second operation may include a sensing operation. The mismatch cancellation operation may remove or compensate for a mismatch or offset between a bit line BL and a complementary bit line BLB by driving the bit line BL and the complementary bit line BLB at the same voltage level. The sensing operation, which is subsequent to the mismatch cancellation operation, may accurately sense data loaded on the bit line BL or the complementary bit line BLB by amplifying a voltage difference between the bit line BL and the complementary bit line BLB.

The first power supply circuit 120 may drive the first power line RTO with an internal voltage VCORE based on a first power control signal RTO_EN. For example, the first power control signal RTO_EN may be activated during the first operation period and the second operation period, and the first power supply circuit 120 may be enabled during the first operation period and the second operation period and supply the internal voltage VCORE to the first power line RTO.

The second power supply circuit 130 may drive the second power line SB with a ground voltage VSS based on a second power control signal SB_EN. For example, the second power control signal SB_EN may be activated during the first operation period and the second operation period, and the second power supply circuit 130 may be enabled during the first operation period and the second operation period and supply the ground voltage VSS to the second power line SB.

The first monitoring circuit 140 may generate a first enable signal EN1 according to variations in the internal voltage VCORE. For example, the first monitoring circuit 140 may compare the internal voltage VCORE with a first threshold voltage VREFC1 and generate the first enable signal EN1 according to the comparison result. When the comparison result indicates that the internal voltage VCORE is higher than the first threshold voltage VREFC1, the first enable signal EN1 may be deactivated. When the comparison result indicates that the internal voltage VCORE is lower than the first threshold voltage VREFC1, the first enable signal EN1 may be activated. The first threshold voltage VREFC1 may be designed to have a voltage level lower than the internal voltage VCORE but similar to the internal voltage VCORE. In this case, the first monitoring circuit 140 may immediately monitor a voltage drop in the internal voltage VCORE and activate the first enable signal EN1. The first monitoring circuit 140 may be a main monitoring circuit that continuously monitors the voltage drop in the internal voltage VCORE.

The second monitoring circuit 150 may generate a second enable signal EN2 according to variations in the internal voltage VCORE. For example, the second monitoring circuit 150 may be enabled based on the first enable signal EN1, compare the internal voltage VCORE with a second threshold voltage VREFC2 and generate the second enable signal EN2 according to the comparison result. When the comparison result indicates that the internal voltage VCORE is higher than the second threshold voltage VREFC2, the second enable signal EN2 may be deactivated. When the comparison result indicates that the internal voltage VCORE is lower than the second threshold voltage VREFC2, the second enable signal EN2 may be activated. Only when the first enable signal EN1 is activated, the second enable signal EN2 may be activated. The second threshold voltage VREFC2 may have a lower voltage level than the first threshold voltage VREFC1. In this case, after the first enable signal EN1 is activated, the second monitoring circuit 150 may monitor a voltage drop in the internal voltage VCORE and activate the second enable signal EN2. The second monitoring circuit 150 may be a first auxiliary monitoring circuit that selectively or conditionally monitors the voltage drop in the internal voltage VCORE.

The third monitoring circuit 160 may generate a third enable signal EN3 according to variations in the internal voltage VCORE. For example, the third monitoring circuit 160 may be enabled based on the first enable signal EN1, compare the internal voltage VCORE with a third threshold voltage VREFC3 and generate the third enable signal EN3 according to the comparison result. When the comparison result indicates that the internal voltage VCORE is higher than the third threshold voltage VREFC3, the third enable signal EN3 may be deactivated. When the comparison result indicates that the internal voltage VCORE is lower than the third threshold voltage VREFC3, the third enable signal EN3 may be activated. Only when the first enable signal EN1 is activated, the third enable signal EN3 may be activated. The third threshold voltage VREFC3 may have a lower voltage level than the second threshold voltage VREFC2. In this case, after the first enable signal EN1 is activated, the third monitoring circuit 160 may monitor a voltage drop in the internal voltage VCORE and activate the third enable signal EN3. The third monitoring circuit 160 may be a second auxiliary monitoring circuit that selectively or conditionally monitors the voltage drop in the internal voltage VCORE.

The first driving circuit 170 may supply a power source voltage VDD to a supply terminal of the internal voltage VCORE based on the first enable signal EN1. For example, the first driving circuit 170 may drive the supply terminal of the internal voltage VCORE with the power source voltage VDD when the internal voltage VCORE is lower than the first threshold voltage VREFC1. The first driving circuit 170 may be enabled during the first operation period in which the mismatch cancellation operation is performed and be enabled during the second operation period in which the sensing operation is performed. More specifically, the first driving circuit 170 may be enabled during almost all of the first operation period and be enabled during almost all of the second operation period. The first driving circuit 170 may be a main driving circuit.

The second driving circuit 180 may supply the power source voltage VDD to the supply terminal of the internal voltage VCORE based on the second enable signal EN2. For example, the second driving circuit 180 may drive the supply terminal of the internal voltage VCORE with the power source voltage VDD when the internal voltage VCORE is lower than the second threshold voltage VREFC2. The second driving circuit 180 may be enabled during the first operation period in which the mismatch cancellation operation is performed and be enabled during the second operation period in which the sensing operation is performed. More specifically, the second driving circuit 180 may be enabled during some of the first operation period and be enabled during some of the second operation period. The second driving circuit 180 may be a first auxiliary driving circuit.

The third driving circuit 190 may supply the power source voltage VDD to the supply terminal of the internal voltage VCORE based on the third enable signal EN3. For example, the third driving circuit 190 may drive the supply terminal of the internal voltage VCORE with the power source voltage VDD when the internal voltage VCORE is lower than the third threshold voltage VREFC3. The third driving circuit 190 may be disabled during the first operation period and be enabled during the second operation period. More specifically, the third driving circuit 190 may be enabled during the first operation period and some of the second operation period. The third driving circuit 190 may be a second auxiliary driving circuit.

Although it is described as an example in the present embodiment that three monitoring circuits, i.e., 140, 150, and 160, and three driving circuits, i.e., 170, 180, and 190 are included in the memory device 100, it is not necessarily limited thereto, and four or more monitoring circuits and four or more driving circuits may be included in the memory device, depending on design.

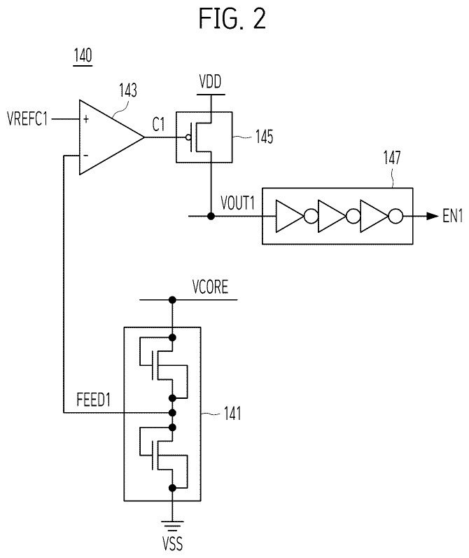

FIG. 2 is a block diagram illustrating in detail the first monitoring circuit 140 illustrated in FIG. 1, in accordance with an embodiment of the present disclosure.

Referring to FIG. 2, the first monitoring circuit 140 may include a first divider 141, a first comparator 143, a first driver 145, and a first generator 147.

The first divider 141 may be coupled between the supply terminal of the internal voltage VCORE and a supply terminal of the ground voltage VSS. For example, the first divider 141 may include diode-coupled NMOS transistors. The first divider 141 may divide the internal voltage VCORE at a predetermined division ratio and generate a first feedback voltage FEED1. For example, the first divider 141 may generate the first feedback voltage FEED1 corresponding to half of the internal voltage VCORE.

The first comparator 143 may compare the first feedback voltage FEED1 with the first threshold voltage VREFC1 and generate a first comparison signal C1 corresponding to the comparison result. For example, the first comparator 143 may activate the first comparison signal C1 when the first feedback voltage FEED1 is lower than the first threshold voltage VREFC1.

The first driver 145 may be coupled between a supply terminal of the power source voltage VDD and a first node VOUT1. For example, the first driver 145 may include a PMOS transistor. The first driver 145 may supply the power source voltage VDD to the first node VOUT1 based on the first comparison signal C1. For example, the first driver 145 may drive the first node VOUT1 with the power source voltage VDD when the first comparison signal C1 is activated. Although it is described as an example in the present embodiment that the first driver 145 uses the power source voltage VDD, it is not necessarily limited thereto, and various voltages, i.e., predetermined voltages, may be used, depending on design.

The first generator 147 may generate the first enable signal EN1 corresponding to a voltage level of the first node VOUT1. For example, the first generator 147 may be a repeater or a buffer. Specifically, the first generator 147 may include an inverter chain in which a plurality of inverters are serially coupled.

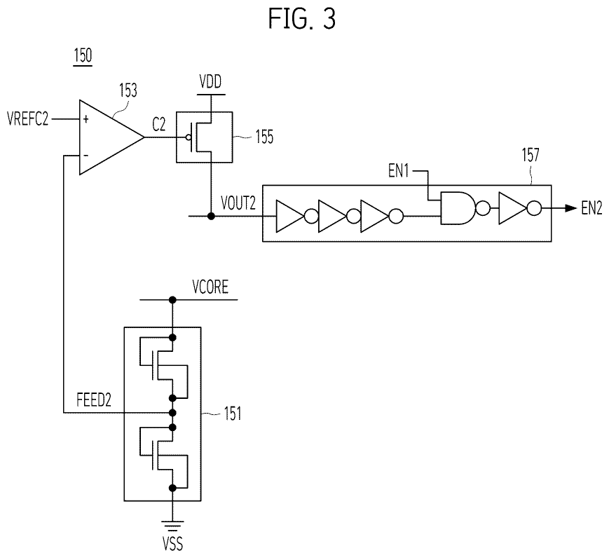

FIG. 3 is a block diagram illustrating in detail the second monitoring circuit 150 illustrated in FIG. 1, in accordance with an embodiment of the present disclosure.

Referring to FIG. 3, the second monitoring circuit 150 may include a second divider 151, a second comparator 153, a second driver 155, and a second generator 157.

The second divider 151 may be coupled between the supply terminal of the internal voltage VCORE and the supply terminal of the ground voltage VSS. For example, the first divider 151 may include diode-coupled NMOS transistors. The second divider 151 may divide the internal voltage VCORE at a predetermined division ratio and generate a second feedback voltage FEED2. For example, the second divider 151 may generate the second feedback voltage FEED2 corresponding to half of the internal voltage VCORE.

The second comparator 153 may compare the second feedback voltage FEED2 with the second threshold voltage VREFC2 and generate a second comparison signal C2 corresponding to the comparison result. For example, the second comparator 153 may activate the second comparison signal C2 when the second feedback voltage FEED2 is lower than the second threshold voltage VREFC2.

The second driver 155 may be coupled between the supply terminal of the power source voltage VDD and a second node VOUT2. For example, the first driver 155 may include a PMOS transistor. The second driver 155 may supply the power source voltage VDD to the second node VOUT2 based on the second comparison signal C2. For example, the second driver 155 may drive the second node VOUT2 with the power source voltage VDD when the second comparison signal C2 is activated. Although it is described as an example in the present embodiment that the second driver 155 uses the power source voltage VDD, it is not necessarily limited thereto, and various voltages, i.e., predetermined voltages, may be used, depending on design.

The second generator 157 may be enabled when the first enable signal EN1 is activated. The second generator 157 may generate the second enable signal EN2 corresponding to a voltage level of the second node VOUT2. For example, the second generator 157 may be a repeater or a buffer that operates based on the first enable signal EN1. Specifically, the second generator 157 may include an inverter chain and a NAND gate.

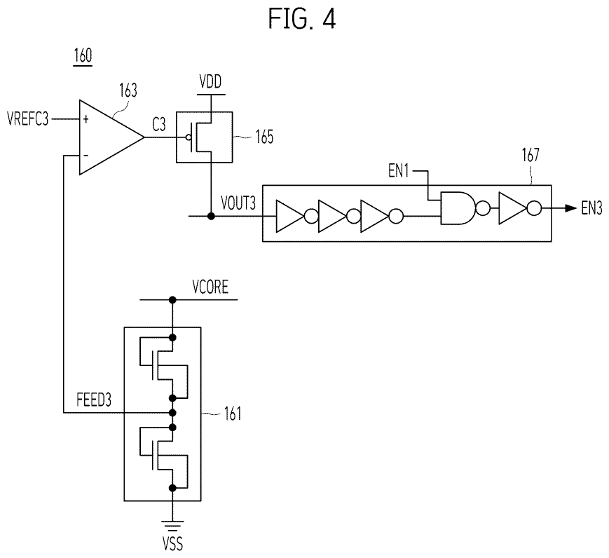

FIG. 4 is a block diagram illustrating in detail the third monitoring circuit 160 illustrated in FIG. 1, in accordance with an embodiment of the present disclosure.

Referring to FIG. 4, the third monitoring circuit 160 may include a third divider 161, a third comparator 163, a third driver 165, and a third generator 167.

The third divider 161 may be coupled between the supply terminal of the internal voltage VCORE and the supply terminal of the ground voltage VSS. For example, the first divider 161 may include diode-coupled NMOS transistors. The third divider 161 may divide the internal voltage VCORE at a predetermined division ratio and generate a third feedback voltage FEED3. For example, the third divider 161 may generate the third feedback voltage FEED3 corresponding to half of the internal voltage VCORE.

The third comparator 163 may compare the third feedback voltage FEED3 with the third threshold voltage VREFC3 and generate a third comparison signal C3 corresponding to the comparison result. For example, the third comparator 163 may activate the third comparison signal C3 when the third feedback voltage FEED3 is lower than the third threshold voltage VREFC3.

The third driver 165 may be coupled between the supply terminal of the power source voltage VDD and a third node VOUT3. For example, the first driver 165 may include a PMOS transistor. The third driver 165 may supply the power source voltage VDD to the third node VOUT3 based on the third comparison signal C3. For example, the third driver 165 may drive the third node VOUT3 with the power source voltage VDD when the third comparison signal C3 is activated. Although it is described as an example in the present embodiment that the third driver 165 uses the power source voltage VDD, it is not necessarily limited thereto, and various voltages, i.e., predetermined voltages, may be used, depending on design.

The third generator 167 may be enabled when the first enable signal EN1 is activated. The third generator 167 may generate the third enable signal EN3 corresponding to a voltage level of the third node VOUT3. For example, the third generator 167 may be a repeater or a buffer that operates based on the first enable signal EN1. Specifically, the third generator 167 may include an inverter chain and a NAND gate.

Although it is described as an example in the present embodiment that the first to third monitoring circuits 140, 150, and 160 include the first to third dividers 141, 151, and 161, respectively, it is not necessarily limited thereto, and the first to third monitoring circuits 140, 150, and 160 may have a structure of sharing a single divider, depending on design. When the first to third monitoring circuits 140, 150, and 160 share the first divider 141, the first to third comparators 143, 153, and 163 included in the first to third monitoring circuits 140, 150, and 160, respectively, may receive in common the first feedback voltage FEED1 generated by the first divider 141.

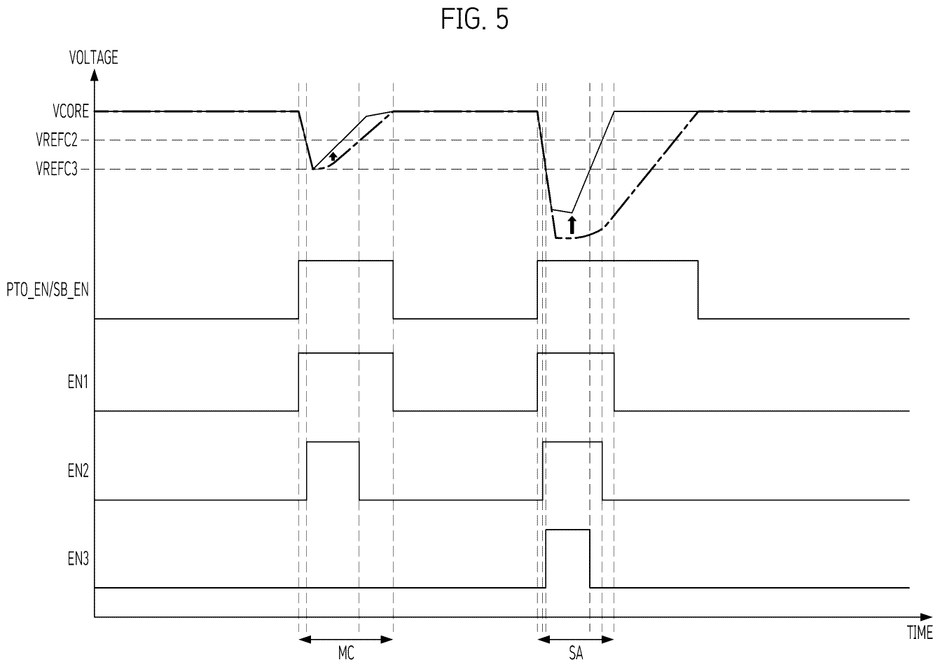

Hereinafter, an operation of the memory device 100 in accordance with an embodiment of the present disclosure, which has the above-described configuration, is described with reference to FIG. 5.

FIG. 5 is a timing diagram for describing an operation of the memory device 100 illustrated in FIG. 1, in accordance with an embodiment of the present disclosure.

Referring to FIG. 5, the memory device 100 may perform a first operation during a first operation period MC and perform a second operation during a second operation period SA subsequent to the first operation period MC. For example, the first operation may include a mismatch cancellation operation, and the second operation may include a sensing operation. The mismatch cancellation operation may remove or compensate for a mismatch or offset between the bit line BL and the complementary bit line BLB by driving the bit line BL and the complementary bit line BLB at the same voltage level. The sensing operation may be subsequent to the mismatch cancellation operation and accurately sense data loaded on the bit line BL or the complementary bit line BLB by amplifying a voltage difference between the bit line BL and the complementary bit line BLB. Because the first operation and the second operation each use the internal voltage VCORE, a voltage drop in the internal voltage VCORE may occur when the first operation and the second operation are performed.

First, the first operation performed during the first operation period MC is described.

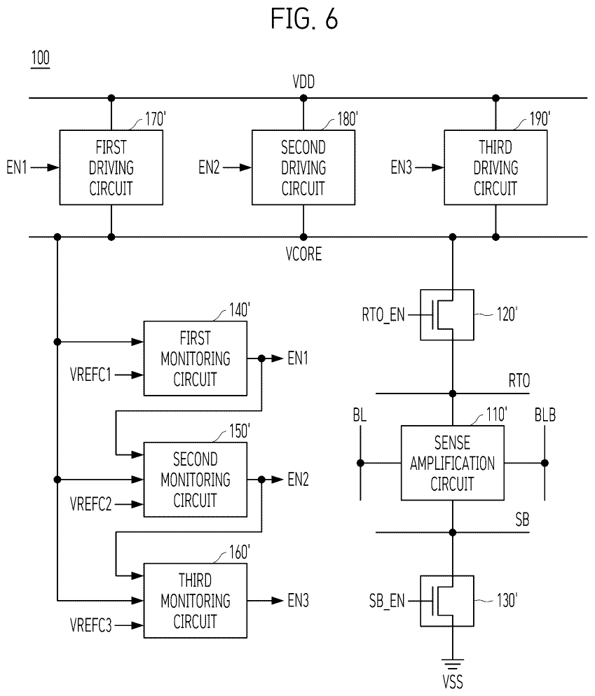

The first monitoring circuit 140 may continuously monitor the voltage drop in the internal voltage VCORE based on the first threshold voltage VREFC1 during the first operation period MC. Although the first threshold voltage VREFC1 is not illustrated in FIG. 6, the first threshold voltage VREFC1 may have a lower voltage level than the internal voltage VCORE but have almost the same voltage level as the internal voltage VCORE.

The first monitoring circuit 140 may activate the first enable signal EN1 when the internal voltage VCORE varies by a first voltage drop amount or more as a result of continuous monitoring during the first operation period MC. The first voltage drop amount may correspond to a result of subtracting a target voltage level of the first threshold voltage VREFC1 from a target voltage level of the internal voltage VCORE.

When the first enable signal EN1 is activated, the first driving circuit 170 may be enabled and supply the power source voltage VDD to the supply terminal of the internal voltage VCORE. In addition, when the first enable signal EN1 is activated, the second monitoring circuit 150 may be enabled and selectively monitor the voltage drop in the internal voltage VCORE based on the second threshold voltage VREFC2 lower than the first threshold voltage VREFC1 during the first operation period MC. That is, the second monitoring circuit 150 may monitor the voltage drop in the internal voltage VCORE only when the first enable signal EN1 is activated, and thus may perform a monitoring operation during some of the first operation period MC.

The second monitoring circuit 150 may activate the second enable signal EN2 when the internal voltage VCORE varies by a second voltage drop amount or more as a result of selective monitoring. The second voltage drop amount may correspond to a result of subtracting a target voltage level of the second threshold voltage VREFC2 from the target voltage level of the internal voltage VCORE.

When the second enable signal EN2 is activated, the second driving circuit 180 may be enabled and additionally supply the power source voltage VDD to the supply terminal of the internal voltage VCORE.

Accordingly, during the first operation period MC, depending on the degree of the voltage drop in the internal voltage VCORE, i.e., the voltage drop amount, only the first driving circuit 170 is enabled, or the first driving circuit 170 and the second driving circuit 180 are enabled together, so that the supply terminal of the internal voltage VCORE may be differentially compensated. The voltage drop amount (indicated by solid lines) of the internal voltage VCORE according to an embodiment of the present disclosure may be reduced as compared to a voltage drop amount (indicated by long and short dash lines) of an internal voltage according to the prior art.

When the first enable signal EN1 is activated, the third monitoring circuit 160 may be enabled and selectively monitor the voltage drop in the internal voltage VCORE based on the third threshold voltage VREFC3 lower than the second threshold voltage VREFC2 during the first operation period MC. However, the third monitoring circuit 160 may continuously deactivate the third enable signal EN3 because the internal voltage VCORE is higher than the third threshold voltage VREFC3 as a result of monitoring during the first operation period MC.

Next, the second operation performed during the second operation period SA is described.

The first monitoring circuit 140 may continuously monitor the voltage drop in the internal voltage VCORE based on the first threshold voltage VREFC1 during the second operation period SA. As described above, although the first threshold voltage VREFC1 is not illustrated in FIG. 6, the first threshold voltage VREFC1 may have a lower voltage level than the internal voltage VCORE but have almost the same voltage level as the internal voltage VCORE.

The first monitoring circuit 140 may activate the first enable signal EN1 when the internal voltage VCORE varies by a first voltage drop amount or more as a result of continuous monitoring. The first voltage drop amount may correspond to a result of subtracting a target voltage level of the first threshold voltage VREFC1 from a target voltage level of the internal voltage VCORE.

When the first enable signal EN1 is activated, the first driving circuit 170 may be enabled and supply the power source voltage VDD to the supply terminal of the internal voltage VCORE.

When the first enable signal EN1 is activated, the second monitoring circuit 150 may be enabled and selectively monitor the voltage drop in the internal voltage VCORE based on the second threshold voltage VREFC2 lower than the first threshold voltage VREFC1 during the second operation period SA. That is, the second monitoring circuit 150 may monitor the voltage drop in the internal voltage VCORE only when the first enable signal EN1 is activated, and thus may perform a monitoring operation during some of the second operation period SA.

The second monitoring circuit 150 may activate the second enable signal EN2 when the internal voltage VCORE varies by a second voltage drop amount or more as a result of selective monitoring. The second voltage drop amount may correspond to a result of subtracting a target voltage level of the second threshold voltage VREFC2 from the target voltage level of the internal voltage VCORE.

When the second enable signal EN2 is activated, the second driving circuit 180 may be enabled and additionally supply the power source voltage VDD to the supply terminal of the internal voltage VCORE.

When the first enable signal EN1 is activated, the third monitoring circuit 160 may be enabled and selectively monitor the voltage drop in the internal voltage VCORE based on the third threshold voltage VREFC3 lower than the second threshold voltage VREFC2 during the second operation period SA. That is, the third monitoring circuit 160 may monitor the voltage drop in the internal voltage VCORE only when the first enable signal EN1 is activated, and thus may perform a monitoring operation during the some of the second operation period SA.

The third monitoring circuit 160 may activate the third enable signal EN3 when the internal voltage VCORE varies by a third voltage drop amount or more as a result of selective monitoring. The third voltage drop amount may correspond to a result of subtracting a target voltage level of the third threshold voltage VREFC3 from the target voltage level of the internal voltage VCORE.

When the third enable signal EN3 is activated, the third driving circuit 190 may be enabled and additionally supply the power source voltage VDD to the supply terminal of the internal voltage VCORE.

Accordingly, during the second operation period SA, depending on the degree of the voltage drop in the internal voltage VCORE, i.e., the voltage drop amount, only the first driving circuit 170 is enabled, or the first driving circuit 170 and the second driving circuit 180 are enabled together, or the first driving circuit 170, the second driving circuit 180 and the third driving circuit 190 are all enabled, so that the supply terminal of the internal voltage VCORE may be differentially compensated. The voltage drop amount (indicated by solid lines) of the internal voltage VCORE according to an embodiment of the present disclosure may be reduced as compared to a voltage drop amount (indicated by long and short dash lines) of an internal voltage according to the prior art.

FIG. 6 is a block diagram illustrating a memory device 100′ in accordance with an embodiment of the present disclosure.

Referring to FIG. 6, the memory device 100′ may include a sense amplification circuit 110′, a first power supply circuit 120′, a second power supply circuit 130′, a first monitoring circuit 140′, a second monitoring circuit 150′, a third monitoring circuit 160′, a first driving circuit 170′, a second driving circuit 180′, and a third driving circuit 190′.

The sense amplification circuit 110′, the first power supply circuit 120′, the second power supply circuit 130′, the first monitoring circuit 140′, the second monitoring circuit 150′, the first driving circuit 170′, the second driving circuit 180′, and the third driving circuit 190′ are the same as the sense amplification circuit 110, the first power supply circuit 120, the second power supply circuit 130, the first monitoring circuit 140, the second monitoring circuit 150, the first driving circuit 170, the second driving circuit 180, and the third driving circuit 190 described in FIG. 1, and therefore, only the third monitoring circuit 160′ is described below.

The third monitoring circuit 160′ may generate a third enable signal EN3 according to variations in an internal voltage VCORE. For example, the third monitoring circuit 160′ may be enabled based on a second enable signal EN2, compare the internal voltage VCORE with a third threshold voltage VREFC3 and generate the third enable signal EN3 according to the comparison result. When the comparison result indicates that the internal voltage VCORE is higher than the third threshold voltage VREFC3, the third enable signal EN3 may be deactivated. When the comparison result indicates that the internal voltage VCORE is lower than the third threshold voltage VREFC3, the third enable signal EN3 may be activated. Only when the second enable signal EN2 is activated, the third enable signal EN3 may be activated. The third threshold voltage VREFC3 may have a lower voltage level than the second threshold voltage VREFC2. In this case, after the second enable signal EN is activated, the third monitoring circuit 160′ may monitor a voltage drop in the internal voltage VCORE and activate the third enable signal EN3. The third monitoring circuit 160′ may be a second auxiliary monitoring circuit that selectively or conditionally monitors the voltage drop in the internal voltage VCORE.

According to embodiments of the present disclosure, a voltage drop in an internal voltage may be prevented, and the internal voltage may be differentially compensated according to a voltage drop amount of the internal voltage.

According to embodiments of the present disclosure, an internal voltage may be monitored and compensated, which makes it possible to prevent a voltage drop in the internal voltage.

According to embodiments of the present disclosure, an internal voltage may be differentially compensated according to a voltage drop amount of the internal voltage, which makes it possible to reduce the recovery time of the internal voltage.

While the embodiments of the present disclosure have been illustrated and described with respect to specific embodiments, the disclosed embodiments are provided for the description, and not intended to be restrictive. Further, it is noted that the embodiments of the present disclosure may be achieved in various ways through substitution, change, and modification that fall within the scope of the following claims, as those skilled in the art will recognize in light of the present disclosure. The embodiments may be combined to form additional embodiments.

What is claimed is:

1. A memory device comprising:
a first driving circuit configured to supply a second voltage to a supply terminal of a first voltage when the first voltage is lower than a first threshold voltage, in response to a first enable signal;
a second driving circuit configured to supply the second voltage to the supply terminal of the first voltage when the first voltage is lower than a second threshold voltage, in response to a second enable signal, the second threshold voltage having a lower voltage level than the first threshold voltage; and
a sense amplification circuit coupled to the supply terminal of the first voltage.

2. The memory device of claim 1, wherein the first enable signal is activated during a first operation period and a second operation period of the sense amplification circuit.

3. The memory device of claim 2, wherein the second enable signal is activated during the second operation period.

4. The memory device of claim 3,
wherein the first operation period includes a period in which the sense amplification circuit performs a mismatch cancellation operation, and
wherein the second operation period includes a period in which the sense amplification circuit performs an operation of sensing data.

5. The memory device of claim 1, wherein the second voltage has a higher voltage level than the first voltage.

6. The memory device of claim 1, further comprising:
a first monitoring circuit configured to monitor a voltage drop in the first voltage based on the first threshold voltage, and generate the first enable signal corresponding to a monitoring result; and
a second monitoring circuit configured to monitor the voltage drop in the first voltage based on the second threshold voltage, and generate the second enable signal corresponding to a monitoring result.

7. The memory device of claim 6, wherein the first monitoring circuit includes:
a first divider configured to divide the first voltage to generate a first feedback voltage;
a first comparator configured to compare the first feedback voltage with the first threshold voltage, and generate a first comparison signal corresponding to a comparison result;
a first driver configured to supply a third voltage to a first node in response to the first comparison signal; and
a first generator configured to generate the first enable signal corresponding to a voltage level of the first node, in response to an enable signal.

8. The memory device of claim 6, wherein the second monitoring circuit includes:
a second divider configured to divide the first voltage to generate a second feedback voltage;
a second comparator configured to compare the second feedback voltage with the second threshold voltage, and generate a second comparison signal corresponding to a comparison result;
a second driver configured to supply a third voltage to a second node in response to the second comparison signal; and
a second generator configured to generate the second enable signal corresponding to a voltage level of the second node, in response to an enable signal.

9. The memory device of claim 1, further comprising:
a driving circuit configured to supply the second voltage to the supply terminal of the first voltage when the first voltage is lower than a threshold voltage, in response to an enable signal; and
a monitoring circuit configured to monitor a voltage drop in the first voltage based on the threshold voltage, and generate the enable signal corresponding to a monitoring result.

10. The memory device of claim 9, wherein the monitoring circuit includes:
a divider configured to divide the first voltage to generate a feedback voltage;
a comparator configured to compare the feedback voltage with the threshold voltage, and generate a comparison signal corresponding to a comparison result;
a driver configured to supply a third voltage to a predetermined node in response to the comparison signal; and
a generator configured to generate the enable signal corresponding to a voltage level of the predetermined node, in response to the enable signal.

11. A memory device comprising:
a sense amplification circuit configured to perform, based on an internal voltage, a first operation during a first operation period and a second operation during a second operation period;
a main driving circuit configured to supply, in response to an enable signal, a predetermined voltage to a supply terminal of the internal voltage when the internal voltage is lower than a threshold voltage during the first operation period and the second operation period, the threshold voltage having a lower voltage level than the internal voltage;
a first auxiliary driving circuit configured to supply, in response to a first enable signal, the predetermined voltage to the supply terminal of the internal voltage when the internal voltage is lower than a first threshold voltage during the first operation period and the second operation period, the first threshold voltage having a lower voltage level than the threshold voltage; and
a second auxiliary driving circuit configured to supply, in response to a second enable signal, the predetermined voltage to the supply terminal of the internal voltage when the internal voltage is lower than a second threshold voltage during the second operation period, the second threshold voltage having a lower voltage level than the first threshold voltage.

12. The memory device of claim 11, further comprising:
a main monitoring circuit configured to monitor a voltage drop in the internal voltage based on the threshold voltage, and generate the enable signal corresponding to a monitoring result;
a first auxiliary monitoring circuit configured to, in response to the enable signal, monitor the voltage drop in the internal voltage based on the first threshold voltage, and generate the first enable signal corresponding to a monitoring result; and
a second auxiliary monitoring circuit configured to, in response to the enable signal, monitor the voltage drop in the internal voltage based on the second threshold voltage, and generate the second enable signal corresponding to a monitoring result.

13. The memory device of claim 12, wherein the main monitoring circuit includes:
a divider configured to divide the internal voltage to generate a feedback voltage;
a comparator configured to compare the feedback voltage with the threshold voltage, and generate a comparison signal corresponding to a comparison result;
a driver configured to supply the predetermined voltage to a predetermined node in response to the comparison signal; and
a generator configured to generate the enable signal corresponding to a voltage level of the predetermined node.

14. The memory device of claim 12, wherein the first auxiliary monitoring circuit includes:
a first divider configured to divide the internal voltage to generate a first feedback voltage;
a first comparator configured to compare the first feedback voltage with the first threshold voltage, and generate a first comparison signal corresponding to a comparison result;
a first driver configured to supply the predetermined voltage to a first node in response to the first comparison signal; and
a first generator configured to generate the first enable signal corresponding to a voltage level of the first node, in response to the enable signal.

15. The memory device of claim 12, wherein the second auxiliary monitoring circuit includes:
a second divider configured to divide the internal voltage to generate a second feedback voltage;
a second comparator configured to compare the second feedback voltage with the second threshold voltage, and generate a second comparison signal corresponding to a comparison result;
a second driver configured to supply the predetermined voltage to a second node in response to the second comparison signal; and
a second generator configured to generate the second enable signal corresponding to a voltage level of the second node, in response to the enable signal.

16. The memory device of claim 11, further comprising:
a main monitoring circuit configured to monitor a voltage drop in the internal voltage based on the threshold voltage, and generate the enable signal corresponding to a monitoring result;
a first auxiliary monitoring circuit configured to, in response to the enable signal, monitor the voltage drop in the internal voltage based on the first threshold voltage, and generate the first enable signal corresponding to a monitoring result; and
a second auxiliary monitoring circuit configured to, in response to the first enable signal, monitor the voltage drop in the internal voltage based on the second threshold voltage, and generate the second enable signal corresponding to a monitoring result.

17. The memory device of claim 16, wherein the main monitoring circuit includes:
a divider configured to divide the internal voltage to generate a feedback voltage;
a comparator configured to compare the feedback voltage with the threshold voltage, and generate a comparison signal corresponding to a comparison result;
a driver configured to supply the predetermined voltage to a predetermined node in response to the comparison signal; and
a generator configured to generating the enable signal corresponding to a voltage level of the predetermined node.

18. The memory device of claim 16, wherein the first auxiliary monitoring circuit includes:
a first divider configured to divide the internal voltage to generate a first feedback voltage;
a first comparator configured to compare the first feedback voltage with the first threshold voltage, and generate a first comparison signal corresponding to a comparison result;
a first driver configured to supply the predetermined voltage to a first node in response to the first comparison signal; and
a first generator configured to generate the first enable signal corresponding to a voltage level of the first node, in response to the enable signal.

19. The memory device of claim 16, wherein the second auxiliary monitoring circuit includes:
a second divider configured to divide the internal voltage to generate a second feedback voltage;
a second comparator configured to compare the second feedback voltage with the second threshold voltage, and generate a second comparison signal corresponding to a comparison result;
a second driver configured to supply the predetermined voltage to a second node in response to the second comparison signal; and
a second generator configured to generate the second enable signal corresponding to a voltage level of the second node, in response to the first enable signal.

20. The memory device of claim 11,
wherein the first operation includes a mismatch cancellation operation of the sense amplification circuit, and
wherein the second operation includes a sensing operation of the sense amplification circuit.

21. An operating method of a memory device comprising:
continuously monitoring, during a first operation period and a second operation period, a voltage drop in an internal voltage based on a first threshold voltage;
supplying, during the first operation period and the second operation period, a predetermined voltage to the supply terminal of the internal voltage according to a result of the continuous monitoring when the internal voltage varies by a first voltage drop amount or more;
selectively monitoring, during the first operation period and the second operation period, the voltage drop in the internal voltage based on a second threshold voltage according to the result of the continuous monitoring; and
additionally supplying, during the first operation period and the second operation period, the predetermined voltage to the supply terminal of the internal voltage according to a result of the selective monitoring when the internal voltage varies by a second voltage drop amount or more.

22. The operating method of claim 21, further comprising:
selectively monitoring, during the second operation period, the voltage drop in the internal voltage based on a third threshold voltage according to a result of the continuous monitoring; and
additionally supplying, during the second operation period, the predetermined voltage to the supply terminal of the internal voltage according to the result of the selective monitoring when the internal voltage varies by a third voltage drop amount or more.

23. The operating method of claim 21, further comprising:
selectively monitoring, during the second operation period, the voltage drop in the internal voltage based on a third threshold voltage according to the result of the selective monitoring; and
additionally supplying, during the second operation period, the predetermined voltage to the supply terminal of the internal voltage according to the result of the selective monitoring when the internal voltage varies by a third voltage drop amount or more.

24. The operating method of claim 21,
wherein a first operation performed during the first operation period includes a mismatch cancellation operation of a sense amplification circuit coupled to the supply terminal of the internal voltage, and
wherein a second operation performed during the second operation period includes a sensing operation of the sense amplification circuit.
